(19) United States
(12) Patent Application Publication
(10) Pub. No.: US 2024/0356505 A1
(43) Pub. Date: Oct. 24, 2024

(54) AMPLIFIER AND METHOD FOR CONTROLLING THE SAME

(71) Applicant: REALTEK SEMICONDUCTOR CORPORATION, HSINCHU (TW)

(72) Inventor: SHIH-HSIUNG HUANG, HSINCHU COUNTY (TW)

(21) Appl. No.: 18/629,498

(22) Filed: Apr. 8, 2024

(30) Foreign Application Priority Data
Apr. 21, 2023 (TW) 112114977

(51) Int. Cl. H03F 3/45

(52) U.S. Cl. CPC H03F 3/45179; H03F 2203/45631

(57) ABSTRACT

The present application discloses an amplifier and a method for controlling the same. The amplifier includes a first P-type transistor, a second P-type transistor, a first N-type transistor and a second N-type transistor. At a first amplification stage, an AC component of a first input signal is amplified into a first amplified signal at a drain of the first P-type transistor. The second P-type transistor then amplifies the first amplified signal and an AC component of a second input signal and outputs at an output terminal.

### CROSS-REFERENCE TO RELATED APPLICATIONS

This application claims priority of Taiwan application No. 112114977 filed on Apr. 21, 2023, which is incorporated by reference in its entirety.

### TECHNICAL FIELD

The present application relates to a circuit; in particular, to an amplifier and a method for controlling the same.

### BACKGROUND

With the advancement of the manufacturing processes, the operating voltage is getting lower and lower. Therefore, how to solve the limitation of output swing while at the same time increasing the gain has become one of the urgent issues to be solved in the related field.

### SUMMARY OF THE INVENTION

The present application provides an amplifier, including: a first P-type transistor, wherein a gate of the first P-type transistor is coupled to a first input signal, and a source of the first P-type transistor is coupled to a first node; a second P-type transistor, wherein a gate of the second P-type transistor is coupled to a second input signal, a source of the second P-type transistor is coupled to a drain of the first P-type transistor, and a drain of the second P-type transistor is coupled to an output terminal; a first N-type transistor, wherein a gate of the first N-type transistor is coupled to a third input signal, and a source of the first N-type transistor is coupled to a second node; a second N-type transistor, wherein a gate of the second N-type transistor is coupled to a fourth input signal, a source of the second N-type transistor is coupled to the drain of the first N-type transistor, and the drain of the second N-type transistor is coupled to the output terminal; a first capacitor, selectively coupled between a first reference voltage and a second reference voltage or between the first node and the second node; a first internal load capacitor, coupled to the drain of the first P-type transistor, and the drain of the first P-type transistor is further selectively coupled to a third reference voltage; and a second internal load capacitor, coupled to the drain of the first N-type transistor, and the drain of the first N-type transistor is further selectively coupled to a fourth reference voltage; wherein in a first amplification stage, an AC component of the first input signal is amplified and a first amplified signal is formed at a drain of the first P-type transistor, and then in a second amplification stage, the second P-type transistor amplifies the first amplified signal and an AC component of the second input signal, and outputs at the output terminal.

The present application provides a method for controlling an amplifier, wherein the amplifier includes: a first P-type transistor, wherein a gate of the first P-type transistor is coupled to a first input signal, and a source of the first P-type transistor is coupled to a first node; a second P-type transistor, wherein a gate of the second P-type transistor is coupled to a second input signal, a source of the second P-type transistor is coupled to a drain of the first P-type transistor, and a drain of the second P-type transistor is coupled to an output terminal; a first N-type transistor, wherein a gate of the first N-type transistor is coupled to a third input signal, and a source of the first N-type transistor is coupled to a second node; a second N-type transistor, wherein a gate of the second N-type transistor is coupled to a fourth input signal, a source of the second N-type transistor is coupled to the drain of the first N-type transistor, and the drain of the second N-type transistor is coupled to the output terminal; a first capacitor, selectively coupled between a first reference voltage and a second reference voltage or between the first node and the second node; a first internal load capacitor, coupled to the drain of the first P-type transistor, and the drain of the first P-type transistor is further selectively coupled to a third reference voltage; and a second internal load capacitor, coupled to the drain of the first N-type transistor, and the drain of the first N-type transistor is further selectively coupled to a fourth reference voltage; and the method includes: before a first amplification stage, controlling the first capacitor to couple between the first reference voltage and the second reference voltage, controlling the drain of the first P-type transistor to couple to the third reference voltage, and controlling the drain of the first N-type transistor to couple to the fourth reference voltage; and controlling the first capacitor to couple between the first node and the second node, controlling the drain of the first P-type transistor to not couple to the third reference voltage, and controlling the drain of the first N-type transistor to not couple to the fourth reference voltage so as to enter the first amplification stage.

The output swing and gain of an amplifier can be increased simultaneously by using the present disclosure.

### BRIEF DESCRIPTION OF THE DRAWINGS

Aspects of the present disclosure are best understood from the following detailed description when read with the accompanying drawings. It is noted that, in accordance with the common practice in the industry, various features are not drawn to scale. In fact, the dimensions of certain features may be arbitrarily increased or reduced for clarity of discussion.

FIG. 1 is a schematic diagram illustrating an amplifier according to certain embodiments of the present disclosure.

FIG. 2 is a schematic diagram illustrating the amplifier according to the present disclosure configured in a first operating phase.

FIG. 3 is a schematic diagram illustrating the amplifier according to the present disclosure configured in a second operating phase.

FIG. 4 is the equivalent circuit of the amplifier according to the present disclosure in a first amplification stage.

FIG. 5 is the equivalent circuit of the amplifier according to the present disclosure in a second amplification stage.

### DETAILED DESCRIPTION

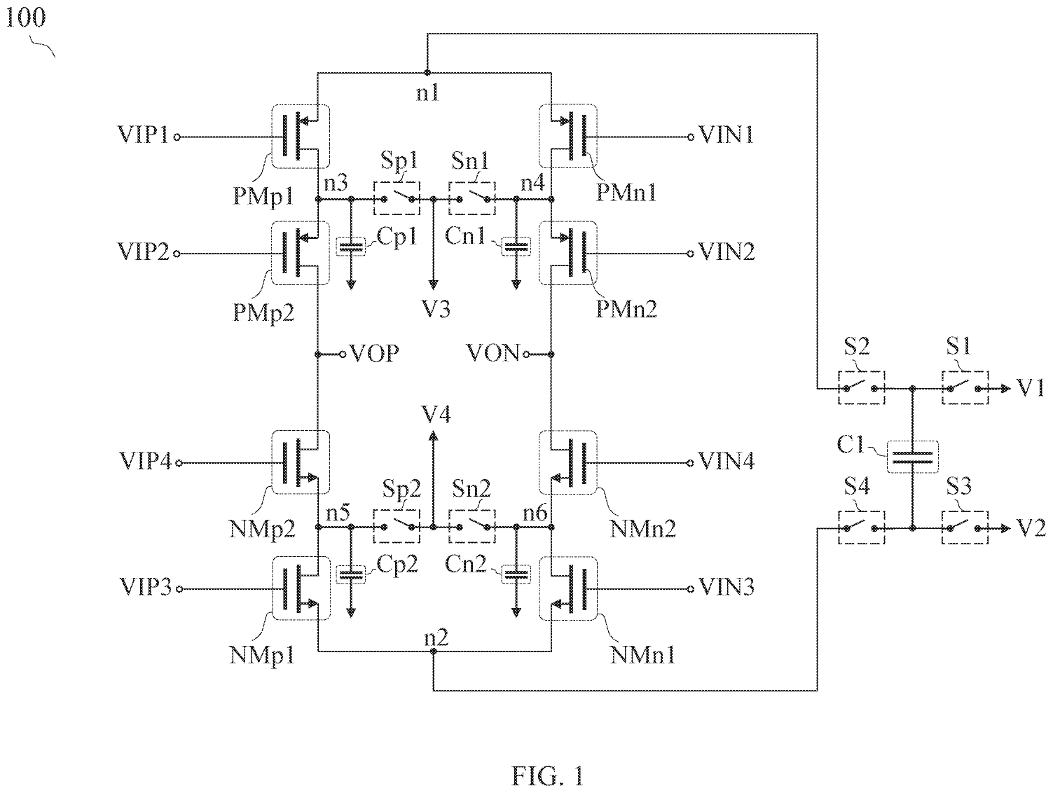

FIG. 1 is a schematic diagram illustrating an amplifier 100 according to certain embodiments of the present disclosure. The amplifier 100 is characterized in that the amplifier 100 is a dynamic amplifier, meaning that the amplifier 100 does not have a constant current source; and the amplifier 100 uses the mechanism of “capacitive degeneration” to automatically stop certain components in the amplifier 100 from performing amplification operations, and the details are described below.

The amplifier 100 includes a differential amplifier body consisting of a first positive terminal P-type transistor PMp1, a second positive terminal P-type transistor PMp2, a first negative terminal P-type transistor PMn1, a second negative terminal P-type transistor PMn2, a first positive terminal N-type transistor NMp1, a second positive terminal N-type transistor NMp2, a first negative terminal N-type transistor NMn1 and a second negative terminal N-type transistor NMn2, which are connected as shown in FIG. 1. Specifically, a node n1 is coupled to the source of the transistor PMp1 and the source of transistor PMn1, wherein the transistor PMp1, the transistor PMp2, the transistor NMp2 and the transistor NMp1 are stacked sequentially and receive an input signal VIP1, an input signal VIP2, an input signal VIP4 and an input signal VIP3 correspondingly from their respective gate; the transistor PMn1, the transistor PMn2, the transistor NMn2 and the transistor NMn1 are stacked sequentially and receive an input signal VIN1, an input signal VIN2, an input signal VIN4 and an input signal VIN3 correspondingly from their respective gate; the node n2 is coupled to the source of transistor NMp1 and the source of transistor NMn1. For case of illustration, the present disclosure further defines nodes n3, n4, n5 and n6, wherein the nodes n3, n4, n5 and n6 are correspondingly coupled to the drains of the transistor PMp1, the transistor PMn1, the transistor NMp1 and the transistor NMn1, and the nodes n3, n4, n5 and n6 are also correspondingly coupled to the sources of the transistor PMp2, the transistor PMn2, the transistor NMp2 and the transistor NMn2.

Moreover, the amplifier 100 further includes a capacitor C1, and internal load capacitors Cp1, Cn1, Cp2 and Cn2, configured to dynamically supply a current to the amplifier 100. Switches S1, S2, S3 and S4 are configured to control the capacitor C1 to be selectively coupled between a reference voltage V1 and a reference voltage V2 or between the node n1 and the node n2. Each of the internal load capacitors Cp1, Cn1, Cp2 and Cn2 has a terminal correspondingly coupled to the nodes n3, n4, n5 and n6. The switches Sp1 and Sn1 are configured to correspondingly control the nodes n3 and n4 to be selectively coupled to the reference voltage V3; the switches Sp2 and Sn2 are configured to correspondingly control the nodes n5 and n6 to be selectively coupled to the reference voltage V4.

In the present embodiment, the internal load capacitors Cp1, Cn1, Cp2 and Cn2 can be the equivalent capacitance of multiple parasitic capacitors of nodes or components in adjacent to the corresponding locations in the circuit, or can be formed by additionally added capacitance components together with the above-mentioned equivalent capacitors.

In the present embodiment, the reference voltage V1 is higher than the reference voltage V2, and the reference voltage V4 is higher than the reference voltage V3. The input signal VIP1 and VIN1 are a differential signal pair, with a common mode DC voltage DC1; the input signal VIP2 and VIN2 are a differential signal pair, with a common mode DC voltage DC2; the input signal VIP3 and VIN3 are a differential signal pair, with a common mode DC voltage DC3; the input signal VIP4 and VIN4 are a differential signal pair, with a common mode DC voltage DC4. The AC components vin+ of the input signals VIP1˜VIP4 are the same, the AC components vin− of the input signals VIN1˜VIN4 are the same; common mode DC voltages DC1˜DC4 can vary as needed.

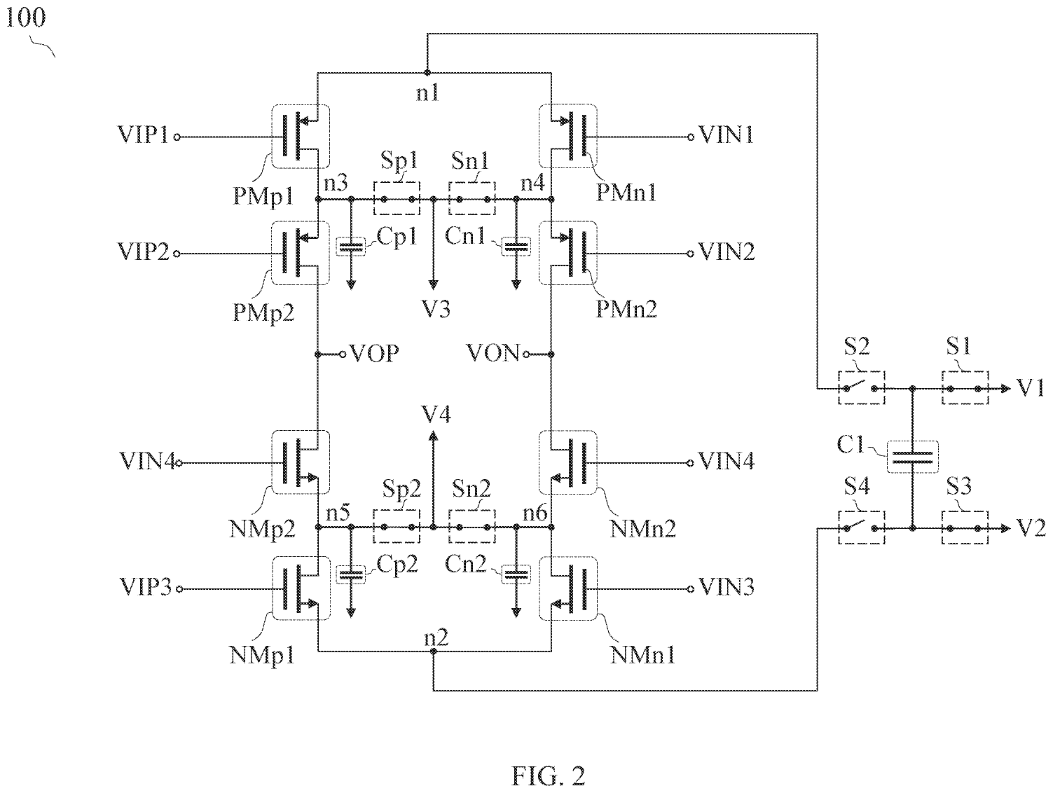

The method for controlling the amplifier 100 can be broadly viewed as having two operating phases; specifically the first operating phase and the second operating phase can be continuously repeated, for example, by simply controlling the switch of the amplifier 100 with a clock signal. In the present embodiment, in the first operating phase, as shown for example in FIG. 2, the switches S2 and S4 are controlled to be disconnected and the switches S1 and S3 to controlled to be connected, so that the first terminal of capacitor C1 is reset to the reference voltage V1 and the second terminal of capacitor C1 is reset to the reference voltage V2. In addition, the switches Sp1, Sn1, Sp2 and Sn2 are controlled to be all conducted so that the respective terminals of capacitors Cp1 and Cn1 are reset to the reference voltage V3; and the respective terminals of capacitors Cp2 and Cn2 are reset to the reference voltage V4.

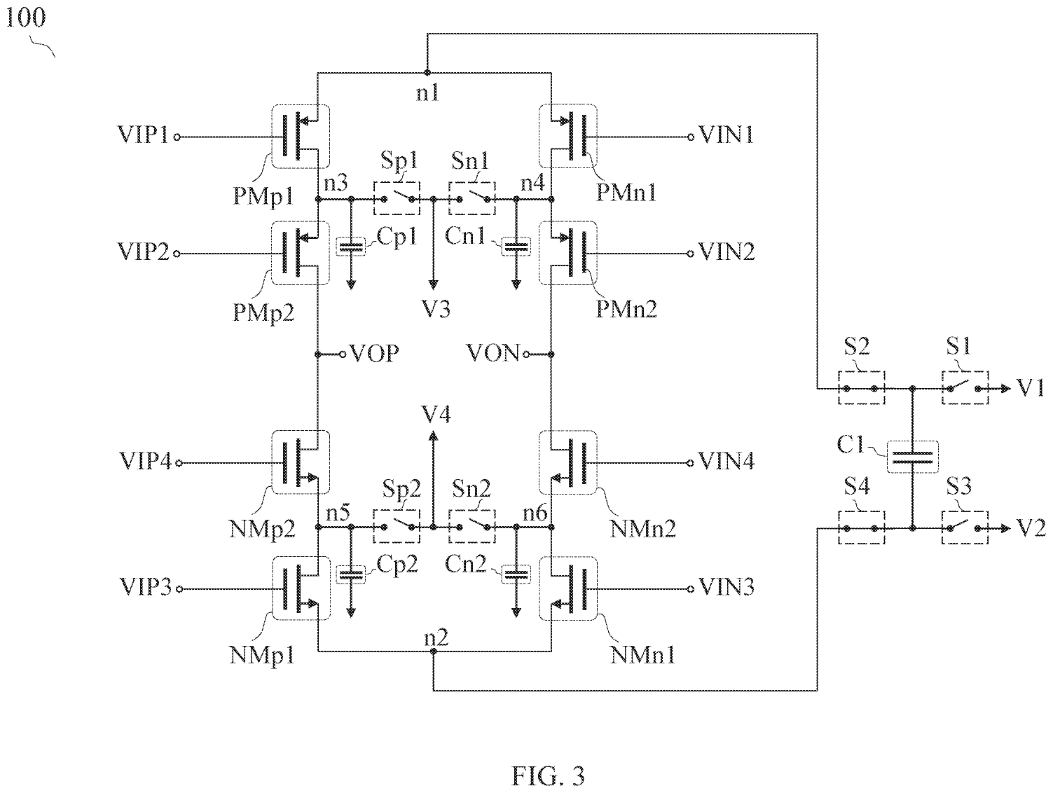

Then, in the second operating phase, as shown in FIG. 3, the switches S2, S4 are controlled to be conducted and the switches S1, S3 are controlled to be disconnected, and the switches Sp1, Sn1, Sn2 are all controlled to be disconnected. The second operating phase sequentially includes a first amplification stage and a second amplification stage, and the first amplification stage starts upon entry into the second operating phase.

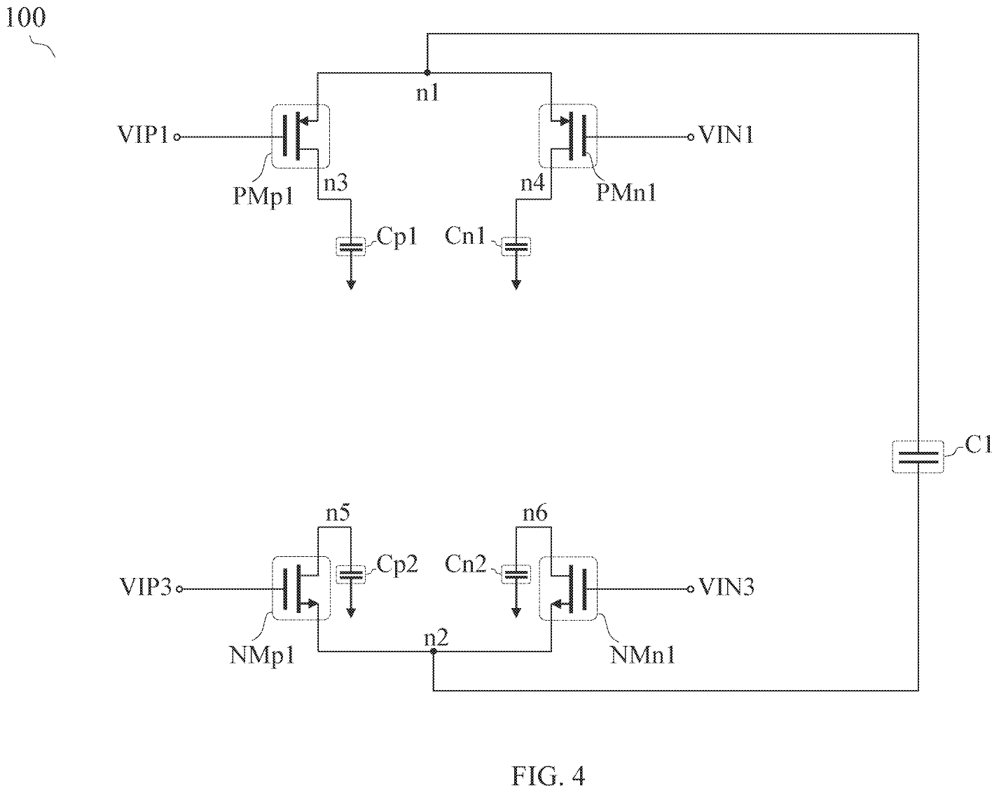

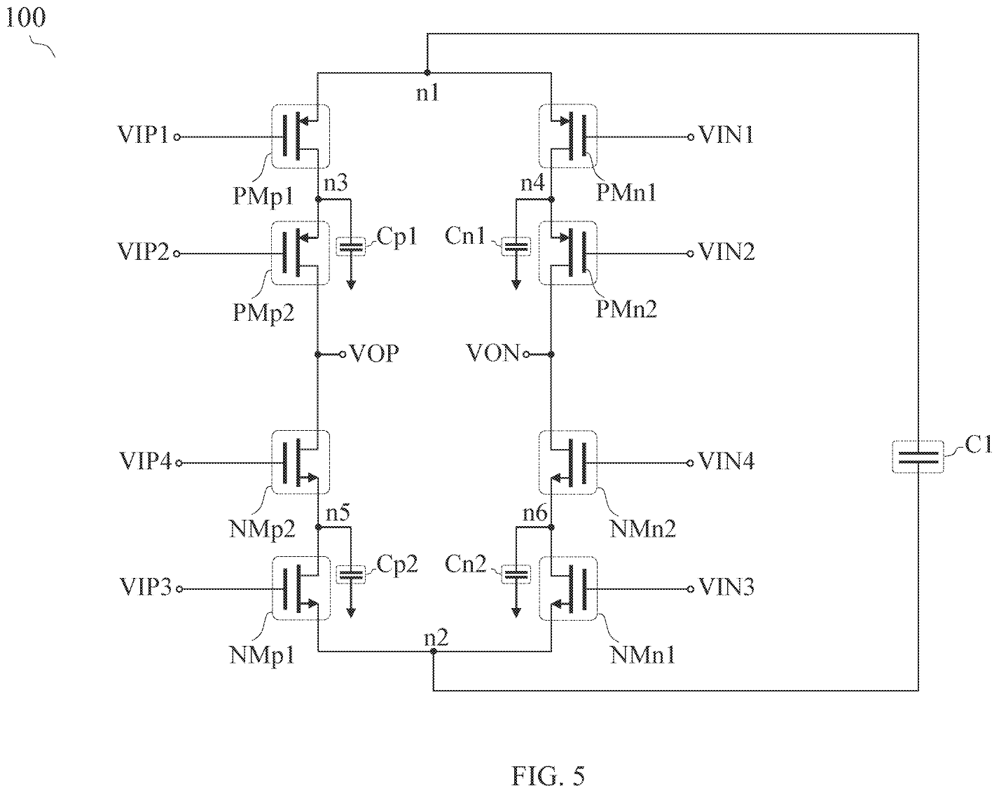

Considering the transistors PMp1, PMp2, PMn1 and PMn2 first, the initial voltage of the node n1 is V1, and because the voltage V1 is high enough, the transistors PMp1 and PMn1 will leave the cutoff region (for example, enter the saturation region) and form a common source dynamic amplifier; whereas the initial voltage of the nodes n3 and n4 is V3, which is low enough so that the transistors PMp2 and PMn2 are in the cutoff region. FIG. 4 shows an equivalent circuit of the first amplification stage of the amplifier 100 operating in the second operating phase. The transistor PMp1 amplifies the AC component vin+ of the input signal VIP1 and generates an amplified signal vin1+ at the node n3, and the transistor PMn1 amplifies the AC component vin− of the input signal VIN1 and generates an amplified signal vin1− at the node n4. At the same time, the charges will continue to flow from the first terminal of the capacitor C1 to the respective terminals of the capacitors Cp1 and Cn1 through the transistors PMp1 and PMn1, so that the voltage of n1 will start to decrease from V1 (thereby making the source-gate voltages of the transistors PMp1 and PMn1 gradually decrease), and that the voltages of nodes n3 and n4 rise from V3 (thereby making the source-gate voltages of transistors PMp2 and PMn2 gradually increase), such that in the end, transistors PMp1 and PMn1 are close to the cutoff region and substantially stop the amplification operation, and the transistors PMp2 and PMn2 leave the cutoff region, that is, the mechanism of “capacitive degeneration” is used to make the amplifier 100 automatically enter the second amplification stage; FIG. 5 shows an equivalent circuit of the second amplification stage of the amplifier 100 operating in the second operating phase. In the second amplification stage, since the nodes n3 and n4 have the same common mode voltage, the transistors PMp2 and PMn2 form a common source dynamic amplifier. The transistor PMp2 not only amplifies the AC component vin+ in the input signal VIP2, but also amplifies the amplified signal vin1+, because the amplified signal vin1+ at the node n3 in effect changes the source-gate voltage of the transistor PMp2, so equivalently, the transistor PMp2 further amplifies the amplified signal vin1+ once again, which is finally reflected on the output terminal VOP. Similarly, the transistor PMn2 not only amplifies the AC component vin− in the input signal VIN2, but also amplifies the amplified signal vin1−, because the amplified signal vin1− at the node n4 in effect changes the source-gate voltage of transistor PMn2, so the transistor PMn2 further amplifies the amplified signal vin1− once again, which is finally reflected on the output terminal VON.

Similarly, for the transistors NMp1, NMp2, NMn1 and NMn2, the initial voltage of the node n2 is V2, and because the voltage V2 is low enough, the transistors NMp1 and NMn1 will leave the cutoff region (for example, enter the saturation region) and form a common source dynamic amplifier; whereas the initial voltage of the nodes n5 and n6 is V4, which is high enough so that the transistors NMp2 and NMn2 are in the cutoff region, as equivalently shown in FIG. 4. The transistor NMp1 amplifies the AC component vin+ of the input signal VIP3 and generates an amplified signal vin2+ at the node n5, and the transistor NMn1 amplifies the AC component vin− of the input signal VIN3 and generates an amplified signal vin2− at the node n6. At the same time, the charges will continue to flow from the respective terminals of the capacitors Cp1 and Cn1 to the second terminal of the capacitor C1 through the transistors NMp1 and NMn1, so that the voltage of n2 will start to rise from V1 (thereby making the gate-source voltages of the transistors NMp1 and NMn1 gradually increase), and that the voltages of nodes n5 and n6 decrease from V3 (thereby making the gate-source voltages of transistors NMp2 and NMn2 gradually increase), such that in the end, transistors NMp1 and NMn1 are close to the cutoff region and substantially stop the amplification operation, and the transistors NMp2 and NMn2 leave the cutoff region, that is, the mechanism of “capacitive degeneration” is used to make the amplifier 100 automatically enter the second amplification stage, as equivalently shown in FIG. 5. In the second amplification stage, since the nodes n5 and n6 have the same common mode voltage, the transistors NMp2 and NMn2 form a common source dynamic amplifier. The transistor NMp2 not only amplifies the AC component vin+ in the input signal VIP4, but also amplifies the amplified signal vin2+, because the amplified signal vin2+ at the node n5 in effect changes the gate-source voltage of the transistor NMp2, so equivalently, the transistor NMp2 further amplifies the amplified signal vin2+ once again, which is finally reflected on the output terminal VOP. Similarly, the transistor NMn2 not only amplifies the AC component vin− in the input signal VIN4, but also amplifies the amplified signal vin2−, because the amplified signal vin2− at the node n6 in effect changes the gate-source voltage of transistor NMn2, so the transistor NMn2 further amplifies the amplified signal vin2− once again, which is finally reflected on the output terminal VON.

It should be noted that in the second amplification stage, although the transistors PMp1, PMn1, NMp1, NMn1 are close to the cutoff region, smaller current can still pass through these transistors so that the charges can sequentially pass through the first terminal of the capacitor C1, then the transistors PMp1, PMp2, NMp2 and NMp1, and then return to the second terminal of the capacitor C1; and so that charges can sequentially pass through the first terminal of the capacitor C1, then the transistors PMn1, PMn2, NMn2 and NMn1, and then return to the second terminal of the capacitor C1.

Moreover, before entering the second operating phase, nodes n1, n2, n3, n4, and the output terminals VOP and VON should be reset so as to clear the residual results from the previous cycle.

In certain embodiments, the gates of the transistors PMp1, PMn1, NMp1 and NMn1 may be coupled to a specific reference voltage in the second amplification stage, to ensure that the transistors PMp1, PMn1, NMp1 and NMn1 do not enter the cutoff region completely to avoid overly limiting the amount of current that can flow through them.

The amplifier 100 in the present embodiment is a differential amplifier, but the operation of the amplifier 100 can also be applied to a single-ended amplifier, for example, the transistor PMn1, the transistor PMn2, the transistor NMn2 and the transistor NMn1, and switches Sn1 and Sn2 can be removed from the amplifier 100 to obtain a single-ended amplifier architecture.

In general, the amplifier 100 of the present disclosure is a dynamic amplifier and therefore allows for a larger output swing, wherein some components of the amplifier 100 are configured as common source amplifiers in the first amplification stage, and the amplifier 100 uses the mechanism of “capacitive degeneration” to automatically configure into another type of common source amplifier to take over the amplification operation in the second amplification stage after the first amplification stage is over, thereby effectively increasing the gain.

What is claimed is:

1. An amplifier, comprising:
a first P-type transistor, wherein a gate of the first P-type transistor is coupled to a first input signal, and a source of the first P-type transistor is coupled to a first node;
a second P-type transistor, wherein a gate of the second P-type transistor is coupled to a second input signal, a source of the second P-type transistor is coupled to a drain of the first P-type transistor, and a drain of the second P-type transistor is coupled to an output terminal;
a first N-type transistor, wherein a gate of the first N-type transistor is coupled to a third input signal, and a source of the first N-type transistor is coupled to a second node;
a second N-type transistor, wherein a gate of the second N-type transistor is coupled to a fourth input signal, a source of the second N-type transistor is coupled to the drain of the first N-type transistor, and the drain of the second N-type transistor is coupled to the output terminal;
a first capacitor, selectively coupled between a first reference voltage and a second reference voltage or between the first node and the second node;
a first internal load capacitor, coupled to the drain of the first P-type transistor, and the drain of the first P-type transistor is further selectively coupled to a third reference voltage; and
a second internal load capacitor, coupled to the drain of the first N-type transistor, and the drain of the first N-type transistor is further selectively coupled to a fourth reference voltage;
wherein in a first amplification stage, an AC component of the first input signal is amplified and a first amplified signal is formed at a drain of the first P-type transistor, and then in a second amplification stage, the second P-type transistor amplifies the first amplified signal and an AC component of the second input signal, and outputs at the output terminal.

2. The amplifier of claim 1, wherein in the first amplification stage, an AC component of the third input signal is amplified and a second amplified signal is formed at the drain of the first N-type transistor, and in the second amplification stage, the second N-type transistor amplifies the second amplified signal and an AC component of the fourth input signal, and outputs at the output terminal.

3. The amplifier of claim 2, wherein in the first amplification stage, the first P-type transistor and the first N-type transistor are not in a cutoff region, the second P-type transistor and the second N-type transistor are in the cutoff region.

4. The amplifier of claim 3, wherein in the first amplification stage, charge flows from a first terminal of the first capacitor through the first P-type transistor into the first internal load capacitor, and charge flows from the second internal load capacitor through the first N-type transistor into a second terminal of the first capacitor.

5. The amplifier of claim 4, wherein in the first amplification stage, a source-gate voltage of the first P-type transistor gradually decreases, a source-gate voltage of the second P-type transistor gradually increases; and a gate-source voltage of the first N-type transistor gradually decreases, and a gate-source voltage of the second N-type transistor gradually increases.

6. The amplifier of claim 5, wherein in the second amplification stage, the first P-type transistor and the first N-type transistor are close to but has not yet entered into the cutoff region, and the second P-type transistor and the second N-type transistor has left the cutoff region.

7. The amplifier of claim 6, wherein in the second amplification stage, charge flows from the first terminal of the first capacitor through the first P-type transistor, the second P-type transistor, the second N-type transistor and the first N-type transistor into the second terminal of the first capacitor.

8. The amplifier of claim 1, wherein the first reference voltage is higher than the second reference voltage, and the fourth reference voltage is higher than the third reference voltage.

9. The amplifier of claim 1, wherein the AC components of the first input signal, the second input signal, the third input signal and the fourth input signal are the same.

10. The amplifier of claim 9, wherein DC components of the first input signal, the second input signal, the third input signal and the fourth input signal are different.

11. A method for controlling an amplifier, wherein the amplifier comprises:
a first P-type transistor, wherein a gate of the first P-type transistor is coupled to a first input signal, and a source of the first P-type transistor is coupled to a first node;
a second P-type transistor, wherein a gate of the second P-type transistor is coupled to a second input signal, a source of the second P-type transistor is coupled to a drain of the first P-type transistor, and a drain of the second P-type transistor is coupled to an output terminal;
a first N-type transistor, wherein a gate of the first N-type transistor is coupled to a third input signal, and a source of the first N-type transistor is coupled to a second node;
a second N-type transistor, wherein a gate of the second N-type transistor is coupled to a fourth input signal, a source of the second N-type transistor is coupled to the drain of the first N-type transistor, and the drain of the second N-type transistor is coupled to the output terminal;
a first capacitor, selectively coupled between a first reference voltage and a second reference voltage or between the first node and the second node;
a first internal load capacitor, coupled to the drain of the first P-type transistor, and the drain of the first P-type transistor is further selectively coupled to a third reference voltage; and
a second internal load capacitor, coupled to the drain of the first N-type transistor, and the drain of the first N-type transistor is further selectively coupled to a fourth reference voltage; and
the method comprises:
before a first amplification stage, controlling the first capacitor to couple between the first reference voltage and the second reference voltage, controlling the drain of the first P-type transistor to couple to the third reference voltage, and controlling the drain of the first N-type transistor to couple to the fourth reference voltage; and
controlling the first capacitor to couple between the first node and the second node, controlling the drain of the first P-type transistor to not couple to the third reference voltage, and controlling the drain of the first N-type transistor to not couple to the fourth reference voltage so as to enter the first amplification stage.

12. The method according to claim 11, wherein the step of controlling the first capacitor to couple between the first reference voltage and the second reference voltage comprises:
controlling the first capacitor to couple between the first reference voltage and the second reference voltage, so that a voltage of a first terminal of the first capacitor equals to the first reference voltage, and so that a voltage of a second terminal of the first capacitor equals to the second reference voltage.

13. The method according to claim 12, wherein the step of controlling the drain of the first P-type transistor to couple to the third reference voltage comprises:
controlling the drain of the first P-type transistor to couple to the third reference voltage, so that a voltage of a first terminal of the first internal load capacitor equals to the third reference voltage.

14. The method according to claim 13, wherein the step of controlling the drain of the first N-type transistor to couple to the fourth reference voltage comprises:
controlling the drain of the first N-type transistor to couple to the fourth reference voltage, so that a voltage of a first terminal of the second internal load capacitor equals to the fourth reference voltage.

15. The method according to claim 14, wherein the step of controlling the first capacitor to couple between the first node and the second node, controlling the drain of the first P-type transistor to not couple to the third reference voltage, and controlling the drain of the first N-type transistor to not couple to the fourth reference voltage so as to enter the first amplification stage comprises:
controlling the first capacitor to couple between the first node and the second node, controlling the drain of the first P-type transistor to not couple to the third reference voltage, so that charge flows from a first terminal of the first capacitor through the first P-type transistor into the first internal load capacitor.

16. The method according to claim 15, wherein the step of controlling the first capacitor to couple between the first node and the second nod, controlling the drain of the first P-type transistor to not couple to the third reference voltage, and controlling the drain of the first N-type transistor to not couple to the fourth reference voltage so as to enter the first amplification stage comprises:
controlling the first capacitor to couple between the first node and the second node, controlling the drain of the first N-type transistor to not couple to the fourth reference voltage, so that charge flows from the second internal load capacitor through the first N-type transistor into a second terminal of the first capacitor.

17. The method according to claim 16, wherein in the first amplification stage, a source-gate voltage of the first P-type transistor gradually decreases, a source-gate voltage of the second P-type transistor gradually increases; and a gate-source voltage of the first N-type transistor gradually decreases, and a gate-source voltage of the second N-type transistor gradually increases.

18. The method according to claim 17, wherein when the first P-type transistor and the first N-type transistor are close to but has not yet enter into a cutoff region, and the second P-type transistor and the second N-type transistor have left the cutoff region, enters a second amplification stage.

19. The method according to claim 18, wherein in the second amplification stage, charge flows from the first terminal of the first capacitor through the first P-type transistor, the second P-type transistor, the second N-type transistor and the first N-type transistor into the second terminal of the first capacitor.

20. The method according to claim 11, wherein the first reference voltage is higher than the second reference voltage, and the fourth reference voltage is higher than the third reference voltage.
